(19) United States
(12) Patent Application Publication
(10) Pub. No.: US 2004/0169236 A1
(43) Pub. Date: Sep. 2, 2004

(54) Process to improve Nwell-Nwell isolation with a blanket low dose high energy implant

(75) Inventors: Seetharaman Sridhar, Richardson, TX (US); Stanton P. Ashburn, McKinney, TX (US); Zhiqiang Wu, Plano, TX (US); Keith A. Joyner, Richardson, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/781,152

(22) Filed: Feb. 17, 2004

Related U.S. Application Data
(62) Division of application No. 10/005,785, filed on Nov. 8, 2001, now abandoned.
(60) Provisional application No. 60/259,298, filed on Dec. 31, 2000.

(51) Int. Cl. H01L 21/8238

(52) U.S. Cl. 257/371

(57) ABSTRACT

Transistor isolation is improved by eliminating the channeling tail of an N well implant. To do this, a low dose, high energy implant of an oppositely charged dopant ion is implanted, targeted at the depth of the channeling tail.

### BACKGROUND AND SUMMARY OF THE INVENTION

This application relates to integrated circuits and their fabrication, and more particularly to ion implantation.

### BACKGROUND

Ion implantation is used in integrated circuit technology for many purposes, including setting of dopant concentration to control resistivity of materials, isolation of devices, and threshold voltage adjustment. Ions of a desired charge are accelerated by electric fields and directed in a beam to the material to be implanted. Depending on the crystal orientation, the molecular structure of silicon (or another implanted material) allows some implanted ions to “channel,” or penetrate deeper into the material than the majority of the implanted ions. This causes an unwanted bimodal distribution of the ions that causes punch through and degrades isolation of the devices. This is a major issue, especially in high resistivity substrates such as the ones used in many high performance process flows.

Improved Device Isolation with Blanket Low Dose High Energy Implant

The present application discloses innovations that improve well-to-well isolation. In the preferred embodiment, this is done by compensating the channeling tail of well implants. A low dose, high energy implant of an oppositely charged dopant is implanted at a depth below the peak of the well implant. These dopants cancel the effects of the channeling tail, and are deep enough not to interfere with transistor performance.

Advantages of the disclosed methods and structures, in various embodiments, can include one or more of the following:

compensates channeling tail of implants;

decreases probability of sub-surface punch through;

high resistivity substrates maintain isolation after implantation;

allows the same process to be used on substrates with different resistivities with a modification to only the blanket implant dose.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a process chamber for implementing the preferred embodiment.

FIG. 2 is a flow chart showing key steps to the innovative process.

FIG. 3 shows a partially fabricated integrated circuit structure using the preferred embodiment.

FIG. 4a depicts a partially fabricated integrated circuit structure, showing the charge distribution within a semiconductor structure.

FIG. 4b depicts a partially fabricated integrated circuit structure according to the preferred embodiment.

FIG. 5a shows a partially fabricated integrated circuit structure.

FIG. 5b shows a partially fabricated integrated circuit structure according to the preferred embodiment.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

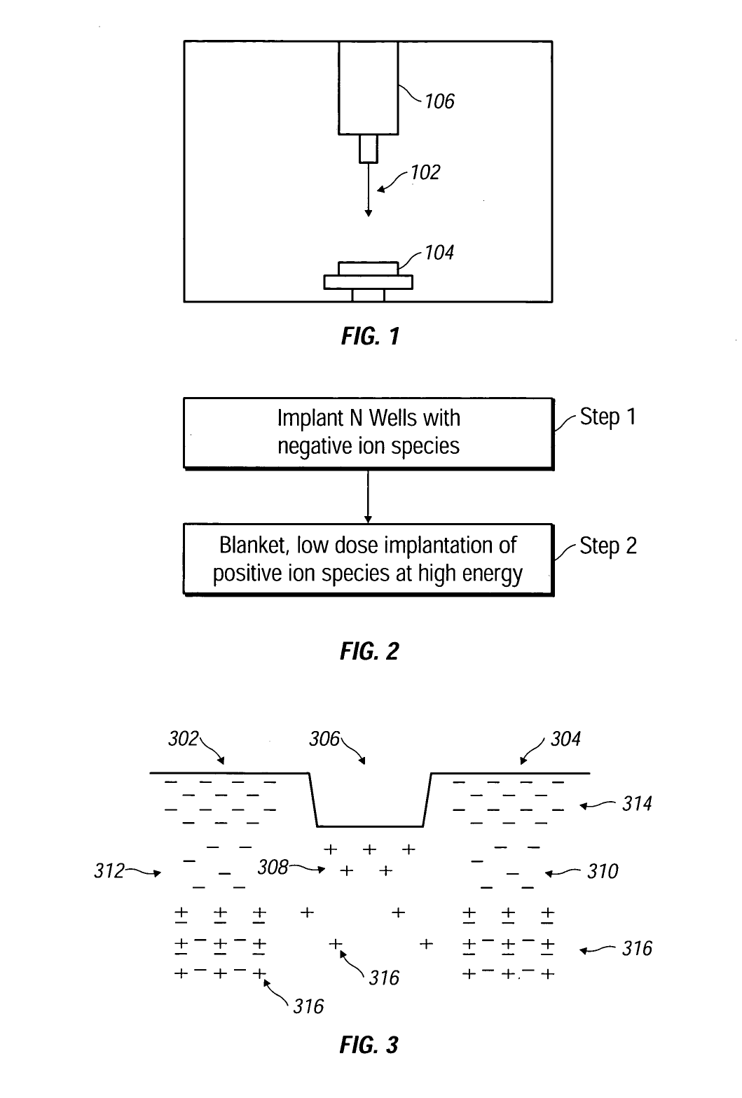

FIG. 1 shows a processing chamber for implementing the preferred embodiment. During device fabrication, ion implantation is used to control dopant concentration in the wafer. Dopants 102 are implanted into the wafer 104 with an ion implantation system 106.

FIG. 2 shows a possible process flow for implementing the preferred embodiment. The individual devices on an IC are implanted with negatively ionized dopants to form N wells in a P substrate (step 1). At a later process step, preferably immediately following the N well implants, a low dose blanket implant of an oppositely ionized species is done at high enough energy to set its peak below that of the N well implant peak (step 2). This later implant is designed to cancel the effects of the channeling tail from the N well implant, which causes implanted ions to be embedded much deeper than the main implant peak.

It should be noted that the exact location of the blanket implant in the process flow may be done either at the start of the process, before the n type implant, or at other process steps, and still be within the contemplation of the present application.

In the preferred embodiment, this compensating implant is a blanket boron implant of low dosage (1×10¹² per square cm) at a high energy (e.g. 775 KeV). (Other energies and doses in this range are of course possible, and other materials can be used instead of boron, such as indium, but energies and doses differ for different species.) The implant energy is high enough so that most of the implanted ions reside at a depth below the main population of N well dopants. The boron doping is tailored to prevent the N well implant channeling tail and is deep enough not to interfere with transistor performance. The dose is also low enough not to affect vulnerability to ESD (electrostatic discharge).

FIG. 3 shows a diagram of a partially fabricated semiconductor structure that demonstrates the preferred embodiment. In this example, two devices 302, 304 are separated by shallow trench isolation 306. Positive ions 308 are implanted to alter the field dopant concentration, preventing current flow between devices 302, 304 in order to keep them electrically isolated. On either side are the N wells 310, 312 of two nearby transistors 302, 304. The negative ions that were implanted to form the N wells 310, 312 have bi-modal distribution. Most of the ions stopped at a shallow depth 314 in the silicon, while others experienced channeling and penetrated to a deeper region 316. The depth of the main N well implant peak is typically about 1-1.5 microns deep, while the channeled ions penetrate to about 1.5-2.0 microns into the substrate.

Next, a low dose of boron ions 316 are blanket implanted at high energy. Implant doses range from 1×10\hat{ }11 to 1×10\hat{ }13 ions per cm\hat{ }2, at energies of 500 to 900 keV. This implant is directed to electrically compensate the channeled N well dopants below the shallow trench isolation. The boron dose is kept low because a relatively low percentage of N well ions experience channeling, the bulk of them residing at the first, more shallow implant peak 314. The energy of the boron implant is high so that the boron ions will penetrate deeply enough to affect the channeling tail of the previous N well implant.

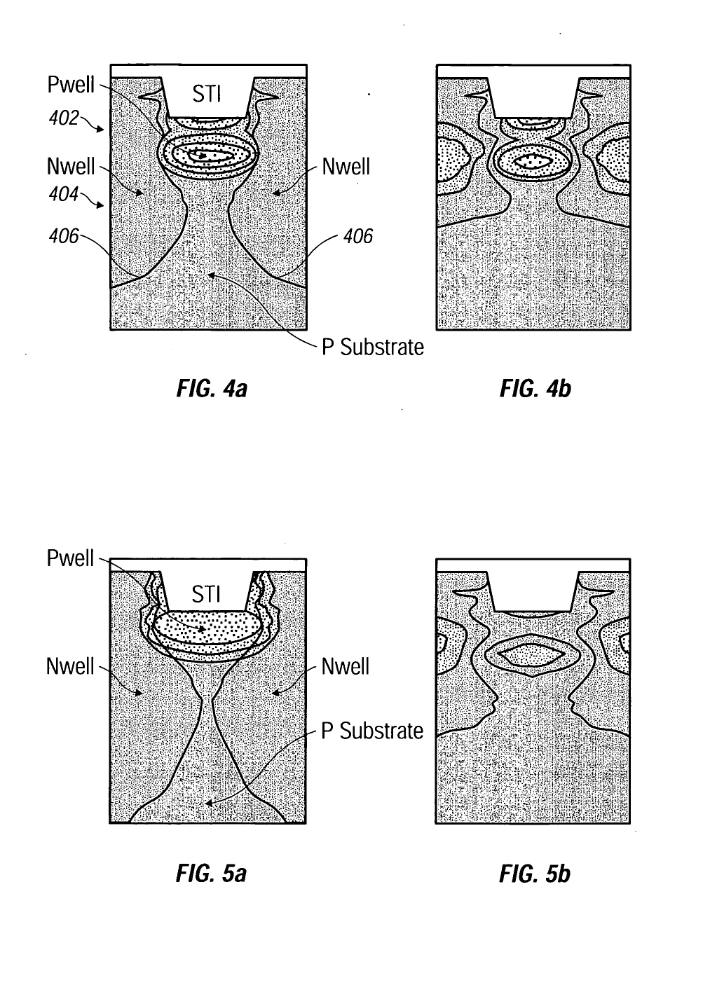

FIG. 4a shows a diagram of a semiconductor substructure. Two devices are separated by shallow trench isolation for devices fabricated using a 2 ohm-cm substrate. There are two distributions of the implanted material. Though most of the dopants stop at a shallow depth 402, some proceed to a deeper level 404 into the wafer due to channeling effects. In this example, the STI separates two N wells from different devices on the IC. The electrically active areas of the N wells are shown by the lines 406 in the substrate. The closer these two regions are to one another, the greater likelihood of punch through (and all its negative effects).

FIG. 4b shows the structure of FIG. 4a, altered by employing the preferred embodiment. As in FIG. 4a, two devices are separated by STI. The channeling tails of the two N wells have been partially compensated by the implantation of oppositely charged ions (in this case, a boron implant of 10\hat{ }12 per cm\hat{ }2 dosage at energy of about 775 keV). This result is shown in the changed positions of the lines #. Note that in this figure, the electrically active areas of the N wells are further separated than in FIG. 4a and thus are better isolated.

FIG. 5a shows another semiconductor substructure of two devices in a 10 ohm-cm P/P+ substrate separated by STI. The lines in the figure represent the junction boundaries (the transition between n and p type) between the n and p wells. Again the channeling effects of the N wells are seen with distributions of dopants penetrating deep into the substrate. The lack of isolation of the N wells of the two devices nearly causes punch through.

FIG. 5b shows the same substructure as seen in FIG. 5a, except that a compensating implantation has been performed, injecting boron ions into the substrate at a greater depth than the STI, into the region of the channeling tail of the N well implants. The implantation of the oppositely charged boron ions cancels the electrical effects of the channeled ions from the N well implants.

According to a disclosed class of innovative embodiments, there is provided: An integrated circuit structure, comprising: NMOS and PMOS transistors, at least some of said PMOS transistors being formed in N-well diffusions in a semiconductor material; and a blanket P-type diffusion component having a peak concentration depth more than twice that of said p-well.

According to another disclosed class of innovative embodiments, there is provided: An integrated circuit structure, comprising: a first population of a first dopant in a semiconductor, said first population occupying a first region of said semiconductor; a second population of said first dopant occupying a second region of said semiconductor, said second region being at a deeper implant depth than said first region; a second dopant occupying said second region of said semiconductor; wherein said second dopant is of opposite electrical ionization than said first dopant.

According to another disclosed class of innovative embodiments, there is provided: A fabrication method, comprising the steps of: a) implanting first dopant atoms into a semiconductor body to create a first-conductivity-type well diffusion therein; and b) implanting second dopant atoms into said semiconductor body, with more than twice the stopping distance and less than one-quarter of the dosage per unit area as said step a), to compensate atoms which channeled during said step a).

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

The crystal orientation of material used for wafer fabrication is carefully controlled, and it is common to use material which is oriented slightly off-axis. Among other benefits, off-axis orientation avoids massive implantation channeling. However, some incident atoms will still be scattered into the channels, resulting in the channeling tail discussed above.

The teachings above are not necessarily strictly limited to silicon. In alternative embodiments, it is contemplated that these teachings can also be applied to structures and methods using other semiconductors, such as silicon/germanium and related alloys, gallium arsenide and related compounds and alloys, indium phosphide and related compounds, and other semiconductors, including layered heterogeneous structures.

What is claimed is:

1. An integrated circuit structure, comprising:
NMOS and PMOS transistors, at least some of said PMOS transistors being formed in N-well diffusions in a semiconductor material; and
a blanket P-type diffusion component having a peak concentration depth more than twice that of said p-well.

2. An integrated circuit structure, comprising:
a first population of a first dopant in a semiconductor, said first population occupying a first region of said semiconductor;
a second population of said first dopant occupying a second region of said semiconductor, said second region being at a deeper implant depth than said first region;
a second dopant occupying said second region of said semiconductor;
wherein said second dopant is of opposite electrical ionization than said first dopant.

3. A fabrication method, comprising the steps of:
a) implanting first dopant atoms into a semiconductor body to create a first-conductivity-type well diffusion therein; and
b) implanting second dopant atoms into said semiconductor body, with more than twice the stopping distance and less than one-quarter of the dosage per unit area as said step a), to compensate atoms which channeled during said step a).
